(19) United States
(12) Patent Application Publication
(10) Pub. No.: US 2011/0159666 A1
(43) Pub. Date: Jun. 30, 2011

(54) DEPOSITION SYSTEMS AND METHODS

(76) Inventor: John P. O'Connor, Andover, MA (US)

(21) Appl. No.: 12/651,183

(22) Filed: Dec. 31, 2009

(51) Int. Cl. H01L 21/36; H01L 21/46

(52) U.S. Cl. 438/478; 118/715; 438/761; 257/E21.461; 257/E21.482

(57) ABSTRACT

Systems, methods, and products made by a deposition process are shown and described. A work piece is supported in a main deposition chamber so that the work piece is positioned above each container of deposition material as the container is moved into and out of the deposition chamber. One or more containers are sequentially moved from each of a plurality of auxiliary chambers into and out of the deposition chamber so as to deposit material from each of the containers onto the work piece in a sequential manner.

### TECHNICAL FIELD

The present subject matter relates to deposition techniques and equipment. In more detail, it relates to techniques and equipment for vapor deposition.

### BACKGROUND

There are various deposition techniques that are used to create semiconductor and other devices requiring careful deposition of material. Some of these devices are used as X-ray detectors in medical imaging systems, such as CT scanners and digital mammography machines. There are two primary types of detectors that convert X-ray photons received by the detectors into electrical signals as a function of the number of photons received. The first type provides indirect conversion. In this type of device, X-ray photons received by a scintillator crystal layer are first converted to visible light, which in turn illuminates a thin film photodetector positioned below the scintillator crystal. The photodiode converts light received from the scintillator crystal into electric signals which are a function of the number of photons received by the scintillator crystal. The second approach is to use direct conversion. In this approach, a photoconductor absorbs the X-ray's directly and generates the electrical signal in response to and as a function of the number of X-ray photons received. A common material used in x-ray detectors is amorphous selenium. Typically, for medical imaging the amorphous selenium must be deposited in precise thicknesses during the manufacturing of the detectors in order to absorb most, if not all, of the X-rays within the expect range of exposure. For example, amorphous selenium detectors should be on the order of approximately 250 microns in order to absorb about 95% of the X-rays in a X-ray medical imaging system such as a CT scanner and digital radiography machine.

Selenium layers are deposited during a vacuum deposition process inside a vacuum deposition chamber. This process is significantly challenging to achieve in a production environment. Many systems use a batch deposition approach. That is multiple substrates, such as TFT panels, are simultaneously mounted inside the chamber, a vacuum is created, and the panels are simultaneously coated during the deposition process. Thus, if a mistake is made during the process it affects each of the multiple panels. Also, selenium leaves a significant level of dusty residue within the chamber following the deposition. It is a non-trivial process to control the particulate level within the process chamber from run-to-run and within the runs themselves. The potential to reduce the particle level within the process chamber and to simplify the cleaning and maintenance processing would provide opportunities for improved productivity with reduced risk of loss of TFT arrays.

### SUMMARY

Described herein are systems and methods for a single-panel approach to amorphous chemical (e.g., selenium) deposition. The system includes a main deposition chamber and a plurality of auxiliary chambers, each adjacent to and connected with the main chamber but separated by a door. Each auxiliary chamber is constructed to allow for the preparation of the deposition material prior to the deposition step which is subsequently carried out in the deposition chamber. The door can be moved between an closed position wherein the pressure and temperature conditions in the corresponding auxiliary chamber can be maintained substantially independent of the deposition chamber, and an open position wherein the prepared deposition material can be moved into the deposition chamber for the deposition step.

In one example, a deposition system is described. The system includes a deposition chamber, a plurality of auxiliary chambers, a support structure, and a control system. The deposition chamber is constructed so that a deposition process can be carried out within the deposition chamber. The plurality of auxiliary chambers are each disposed adjacent to the deposition chamber and separated by a corresponding door movable between a closed position and a open position. The auxiliary chambers can be maintained at a separate pressure and temperature from the deposition chamber when the door is in the closed position Also, a container of material disposed within the auxiliary chamber can be moved into and out of the deposition chamber.

The support is constructed and arranged within the deposition chamber for supporting a work piece so that the work piece is positioned above each container as the container is moved into and out of the deposition chamber. The control subsystem sequentially moves the container of material from each of the auxiliary chambers into and out of the deposition chamber so as to deposit material from each of the containers onto the work piece in a sequential manner.

In some examples, the control subsystem is configured and arranged to proceed through a sequence of steps for each of the auxiliary chambers. The steps include equalizing the temperature and pressure in an auxiliary chamber and the deposition chamber and opening the door therebetween. The steps also include moving the container from the auxiliary chamber into the deposition chamber so as to deposit material from the container onto the work piece, moving the container back to the corresponding auxiliary chamber and closing the door, and subsequently repeating the sequence of steps for each of the auxiliary chambers.

The auxiliary chamber can be arranged so as to prepare the material in the container so that when moved into the deposition chamber the material can be vaporized below and deposited on the work piece. The system can also include a pumping subsystem for separately creating a vacuum in each of the auxiliary chambers and the deposition chamber. Also, the support, in some cases, is rotatably supported in the deposition chamber so that the work piece can be supported upside down, and rotated while a container is below it in the deposition chamber.

A deposition system can also include a plurality of the containers and a removable cover for each of the containers so that when the container is positioned in an auxiliary chamber it can be covered and the material in the container prepared for a deposition process in the deposition chamber, and when the container is positioned in the deposition chamber, the cover can be removed and the material can be vaporized below and deposited on the work piece.

The system can also include a heating subsystem for heating each auxiliary chamber so that the material in a container disposed within the auxiliary chamber can be heated to a molten state prior to the container being moved into the deposition chamber. In some cases, the containers include at least one material different from the material in the other containers. The materials can include p-type selenium and another material comprises n-type selenium.

In another instance, a method of making a semiconductor component in a system is shown and described. The system includes a deposition chamber constructed so that a deposition process can be carried out within the deposition chamber, and a plurality of auxiliary chambers each disposed adjacent to the deposition chamber and separated by a corresponding door movable between a closed position wherein the auxiliary chamber can be maintained at a separate pressure from the deposition chamber, and an opened position wherein a container of material disposed within the auxiliary chamber can be moved into and out of the deposition chamber. The method supporting a work piece so that the work piece is positioned above each container as the container is moved into and out of the deposition chamber and sequentially moving a container of material from each of the plurality of auxiliary chambers into and out of the deposition chamber so as to deposit material from each of the containers onto the work piece in a sequential manner.

In some cases, the method includes equalizing the pressure in an auxiliary chamber and the deposition chamber, opening the door therebetween, moving the container from the auxiliary chamber into the deposition chamber so as to deposit material from the container onto the work piece, moving the container back to the corresponding auxiliary chamber and closing the door, and subsequently repeating the sequence of steps for each of the auxiliary chambers. The method can also include preparing the material in each container so that when moved into the deposition chamber the material can be vaporized below and deposited on the work piece. In some instances, the method also includes separately creating a vacuum in each of the auxiliary chambers and the deposition chamber.

In some instances, the method can include covering each container when the container is positioned in an auxiliary chamber so that the material in the container can be prepared for a deposition process in the deposition chamber and uncovering the container when the container is positioned in the deposition chamber so that the material in the container can be vaporized below and deposited on the work piece. Heating can occur in each auxiliary chamber so that the material in a container disposed within the auxiliary chamber can be heated to a molten state prior to the container being moved into the deposition chamber.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a functional block diagram of an embodiment of a deposition system.

FIG. 2A is a function block diagram of an embodiment of a portion of the deposition of FIG. 1 prior to the deposition material entering the main chamber.

FIG. 2B is a function block diagram of an embodiment of a portion of the deposition of FIG. 1 after the deposition material entering the main chamber.

FIG. 3 is a flow chart of an embodiment of a deposition method.

FIG. 4 is a block diagram of an embodiment of a product produced by the process and systems described herein.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The various examples disclosed herein relate to deposition systems, deposition methods, and products produced by the deposition systems and deposition methods. In one instance, single-panel deposition systems and methods are shown and described. In one example, a system and method are described that achieve a controlled deposition of selenium (Se) or Se-based alloys onto a work piece such as a thin film transistor (TFT) substrate. In one example, the work piece is about 190 square inches. Of course, the described systems and methods can be used in the deposition of materials other than selenium or Se-based alloys.

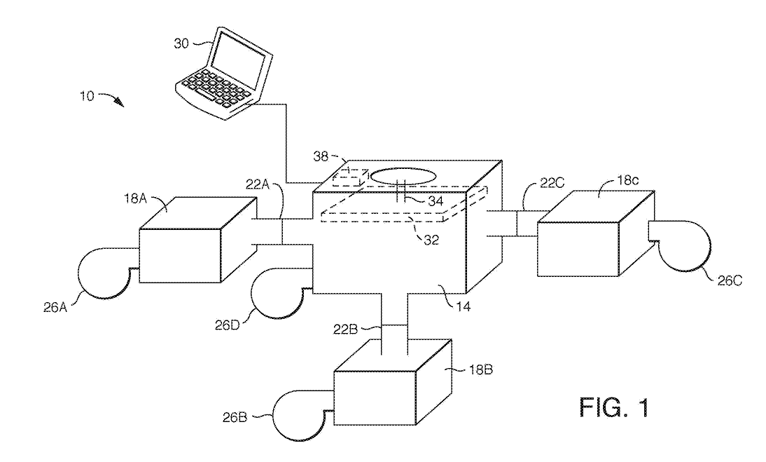

Reference now is made in detail to the examples illustrated in the accompanying drawings and discussed below. FIG. 1 depicts an embodiment of a deposition system 10. Included in the system 10 is a main deposition chamber 14, one or more auxiliary chambers 18A, 18B, 18C (referred to generally as auxiliary chamber 18) in communication with the main chamber 14 via a respective slot valve 22A, 22B, 22C (referred to generally as slot valve 18). Associated with the main chamber 14 and the auxiliary chambers 18 is a respective pressure control system 26A, 26B, 26C, 26D (referred to generally as pressure control system 26) that controls the vacuum pressure within their respective chambers. The system 10 also includes a control system 30 that controls the deposition process by changing and controlling the vacuum pressure within the various chambers, the opening and closing of the slot valves 22, and other aspects of the system 10. For example, the control system 30 can control the rotation of a work piece 32 within the main chamber 14 during the deposition process, the introduction of deposition material within the main chamber 14, and the movement of one or more deposition containers (which are also referred to as boats throughout the specification) that house the deposition material within the main chamber 14 during the deposition process.

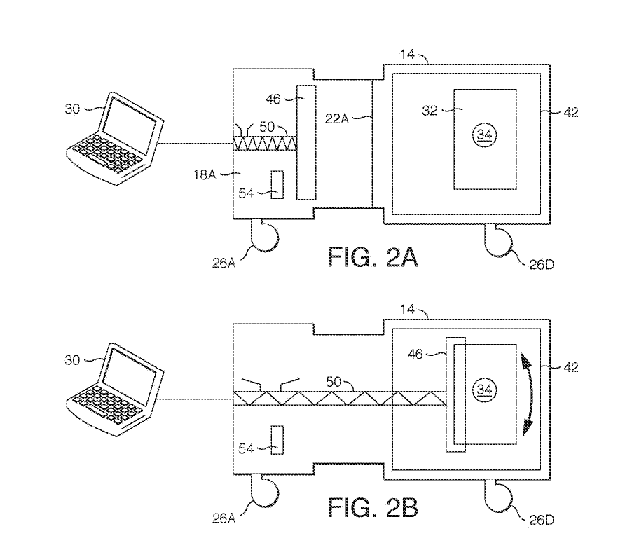

The main chamber 14 is constructed and configured such that a deposition process can be carried out within the chamber. As such, the main chamber 14 includes a top, a bottom, and four side walls. A support structure 34 is constructed and arranged within main chamber 14. The support structure 34 is in contact with the work piece 32 (e.g., a substrate such as a TFT array) and maintains the work piece such that a face of the work piece is substantially parallel to the bottom of the main chamber 14 and when deposition material chambers are moved within the chamber the deposition face of the work piece 32 is positioned above the containers. The support structure 34 is rotatable in either direction under control of the control system 30 to rotate the work piece 32 during the deposition process. Also included in the main chamber 14 is a sensor 38. The sensor 18 measures the amount of deposition material deposited on the work piece 30. In some configurations, a removable liner (which is described in more detail in FIGS. 2A and 2B) is employed. The main chamber 14 is sized according the desired application.

Each auxiliary chamber 18 also defines a volume. The auxiliary chambers 18 house containers (e.g., boats) that hold the deposition materials. The auxiliary chambers 18 facilitate the preparation of the deposition materials in a volume separate from the main chamber 14. For example, an associated heater unit (not shown) can be used to heat an amount of selenium to a molten state in the auxiliary chamber 18A. Thus, any undesirable vapors or splattering are not introduced into the main chamber 14 where they could potential damage the work piece 32. The size of the auxiliary chambers 18 are also application dependent. For example, if a deposition boat is 14 inches wide the auxiliary chamber needs to be able to house the boat. Although three auxiliary chambers 18 are shown, greater or fewer auxiliary chambers 18 can be used depending on the deposition process.

Each slot valves 22 connects a respective auxiliary chamber 18 to a portion (e.g., side wall) of the main chamber 14. The slot valves 22 act as doors between the main chamber 14 and the respective auxiliary chamber 18. The slot valves 22 are sized to allow the containers housing the deposition material to fit through the slot valve 22. Thus, if the container is 16 inches in width, the slot valve is also at least 16 inches in width. Although shown as slot valves, it should be understood that other devices can be used to control the interaction between the main chamber 14 and the auxiliary chambers 18.

Each of the main chamber 14 and auxiliary chambers 18 includes a respective pressure control system 26 that is under the control of the control system 30 during operation. The respective pressure control systems 26 allow individual control of the pressure within each chamber. In some configurations, the pressure control systems 26 are vacuum pumping systems that create a vacuum within the chambers. The vacuum settings within the auxiliary chambers 18 can be different from one another and the main chamber 14 during various times of the deposition method. Also, the vacuum pressure within the one or more of the auxiliary chambers can be substantially equal to the vacuum pressure within the main chamber 14. For example, when the boat from auxiliary chamber 18A is introduced into the main chamber 14, the vacuum pressures within each chamber should be substantially equal in order to prevent venting of one of the chambers into the other. However, during the preparation of the deposition material, it may be beneficial to have the vacuum pressure of the auxiliary chamber 18A at a level different from the main chamber 14.

The control system 30 can be one or more computing systems that execute programmed instructions to control the operation of the various components of the system 10. Also, the control system can receive inputs from the components of the system (e.g., sensor 38, pressure system 26, etc) and process those inputs as part of a closed loop feedback system. Various general purpose (e.g., personal computers) and specialty purpose computing device (e.g., digital signal processors, microcontrollers, etc) can be used as part of the control system. Also, the control system can communicate with one or more components of the system 10 via a communication network. Also, the control can itself include networked computing components.

With reference to FIG. 2A, a block diagram showing the interaction between the auxiliary chamber 18A, the slot valve 22A, and main chamber 14 prior to the introduction of the deposition material into the main chamber 14. As shown, the work piece 32 is attached to the support structure 34 such that a face of the work piece 32 that receives the deposition material is facing in the bottom of the main chamber 14. Thus, when the deposition material (e.g., selenium, a selenium-based alloy, or some other material) is brought into the main chamber and exposed therein, the material is deposited on the face of the work piece 32 opposite the face of the work piece 32 in contact with the support structure 34. The slot valve 22 is closed and the environments within the main chamber 14 and auxiliary chamber 18 are separated.

Also, the main chamber 14 includes a removable liner 42 disposed within the chamber 14. The liner 42 substantially covers the inside of the main chamber 14. The liner 42 may also cover a portion of the main chamber 14 as opposed to the entire main chamber 14. The liner 42 can be of a single piece construction or constructed of multiple sections. The liner can be of aluminum foil is some examples. Of course, other materials can be used. The liner 14 decreases the time required to clean the main chamber 14 in between production runs. The liner 14 can be removed and discarded. Also, when aluminum foil is used the likelihood of contaminants being introduced during the deposition process is reduced.

In the auxiliary chamber 18, a container 46 is connected to a drive screw 50 or some other controllable or moveable mechanism. The container 46, which is sometimes referred to as a boat, holds a deposition material such as a p-type selenium, n-type selenium, i-type selenium, a selenium-based alloy, or some other material. The container 46 includes a cover (not shown) that is movable between an open position and a closed position. The container is sized such that is substantially covers a dimension of the work piece 32. Thus, the entire work piece 32 can be covered in one dimension. For example, if the work piece is 14 inches wide a container with a 16 inch width can substantially cover the work piece. Said another way, the container 46, in one configuration, is an elongated rectangular solid so that the “long” dimension is longer that the work piece 32.

The drive screw 50 is under control of the control system 30 and moves into the main chamber 14 from the auxiliary chamber 18 and back as required. In addition, the drive screw 50 causes, in some examples, the container 46 across and back the main chamber 14 one or more times and one or more rates of travel. The motion of the drive screw 50, in one example, drives the container 46 in an orthogonal direction to the long dimension of the container 46.

When the container is in the auxiliary chamber 18, a heater 54 can be used to prepare the deposition materials as required. In the case of selenium, the heater 54 causes the selenium to reach a molten state in preparation for deposition within the main chamber 14. The heater 54 can be electric in nature. Of course, other types of heaters can be used. Also, during the preparation process the pressure control system 26A can set the vacuum pressure within the auxiliary chamber 18 to a setting that is appropriate for preparing the deposition material. In some instances, the main chamber 14 is set to a different vacuum pressure than the auxiliary chamber 18. However, prior to placing the prepared deposition material into the main chamber 14 the pressure control system 26A adjusts the vacuum pressure with in the auxiliary chamber 18 to be substantially equal to that within the main chamber 14.

With reference to FIG. 2B, after equalizing the pressures within the main chamber 14 and the auxiliary chamber 18 the slot valve 22 is opened and the drive screw 50 is actuated to move the container 46 into the main chamber 14. The work piece 32 rotates, in some examples, when the deposition material is within the main chamber 14. Rotating the work piece 32 can provide for a more uniform deposition of the deposition material. Once in the main chamber 14, the cover of the container 46 is removed and the deposition material is exposed to the environment within the main chamber 14. The nature of the prepared deposition material, in some examples, causes the deposition material to propagate upwards to the deposition face of the work piece 32. Also, depending on the deposition process, the container 46 can traverse the main chamber 14 one or more times and one or more rates of travel. This can also improve the uniformity of deposition of the deposition material on the work piece 32. After the appropriate amount of deposition material is deposited, the container 46 is removed from the main chamber 14 using the drive screw 50 and slot valve 22 is closed. This above process can be repeated with additional containers 46 from the other auxiliary chambers 18. Also, the original container 46 can be cleaned and a second deposition material can be prepared therein and deposited on the work piece 32. That is, a single auxiliary chamber 18 and container 46 can be used to deposit multiple deposition materials. After the work piece 32 is completed, the main chamber 14 is vented and the liner 14 is removed.

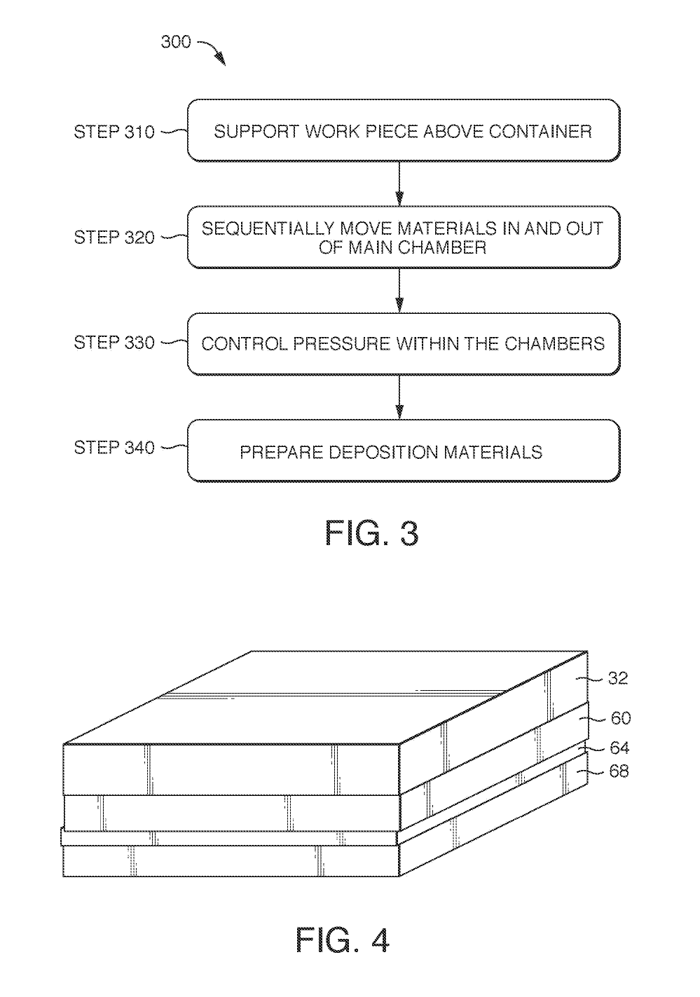

With reference to FIG. 3, a deposition method 300 is shown and described. The method 300 includes supporting (step 310) the work piece 32 within the main chamber 14 and sequentially moving (step 320) the deposition materials in and out of the main chamber 14. In some instances, the method 300 can also include controlling (step 330) the pressure within each of the main chamber 14 and the auxiliary chambers 18 and preparing (step 340) the deposition materials within the auxiliary chambers 18.

In more detail, the work piece 32 is supported (step 310) by the support structure 34 in the main chamber. The support structure 34 can be a feedthrough assembly that rotates the work piece 32 during the deposition process. A face of the work piece 32 is attached to the support structure and the opposite face receives the deposition material.

Depending on the deposition processes, one or more containers 46 are sequentially moved (step 320) into and out of the main chamber 14 from the one or more auxiliary chambers 18. For example, if the resulting product is a P-I-N type photon-detector for use in mammography or other imaging techniques then three different deposition materials are used. First, the p-type selenium is deposited by moving a container 46 of this type of material into and out of the main chamber 14 from one of the auxiliary chambers 18. Second, the i-type selenium is deposited by moving a container 46 of this type of material into and out of the main chamber 14 from one of the auxiliary chambers 18. Lastly, the n-type selenium is deposited by moving a container 46 of this type of material into and out of the main chamber 14 from one of the auxiliary chambers 18.

As described above, the containers 46 are opened and moved across the main chamber 14 one or more times. The amount of time the deposition materials are exposed in the main chamber controls the thickness of the material that is deposited. In order to improve the uniformity of the deposition, the work piece 32 rotates as the container traverses the main chamber 14.

Also, depending on the deposition process the pressure within each of the chambers is controller (step 330) during the process. By providing each chamber with a respective pressure control system 26, the pressures within the chambers can be accurately controlled. For example, when producing a P-I-N type photon-detector, the main chamber 14 is typically pumped down to a vacuum pressure of 10⁻³ torr. During the preparation of the deposition material the auxiliary chamber 18 may be a vacuum pressure different from that of the main chamber 14. However, prior opening the slot valve 22 the pressure within the auxiliary chamber 18 is drawn down to be substantially equal to that of the main chamber 14 (e.g., 10⁻³ torr). Thus, when the slot valve 22 is opened the main chamber 14 does not vent into the auxiliary chamber 18 or vice-versa.

Prior to placing the container 46 into the main chamber 14, the deposition material is prepared (step 340) in the auxiliary chamber 18. For example, a p-type selenium is placed in the container 46. The heater 54 operates to heat the p-type selenium to 250 degrees Celsius. Thus, the p-type selenium is in a molten state. The heating can occur at many pressure settings of the auxiliary chamber 18. The cover of the container 46 is closed on the molten selenium prior to entering the main chamber. Also the preparation of the deposition material involves heating, depending on the deposition processes and materials, preparing the materials can also include cooling, freezing, vaporizing, mixing, and other known techniques.

Also, when multiple auxiliary chambers are used the preparation of additional deposition materials can occur in parallel with other steps of the method 300. For example, during the deposition of the p-type selenium material the i-type material can be heated in a second auxiliary chamber 18B. Thus when the p-type material is returned to the auxiliary chamber 18, the i-type material is ready to be moved into the main chamber 14. Such parallel preparation can increase the throughput of the system 10.

With reference to FIG. 4, a product (e.g., Se-based photon-detector, semiconductor devices, etc.) made the above described processes is shown and described. In one example, the work piece 32 (e.g, a TFT substrate) has deposited thereon a first layer 60 of deposition material, a second layer 64 of deposition material, and a third layer 68 of deposition material. The first layer 60 can be a p-type selenium material, the second layer 64 can be an i-type selenium material, and the third layer 68 can be an n-type selenium material. Of course, the order of the layers can be reversed. Also, additional or fewer layers can be included.

Those skilled in the art will recognize that the present teachings are amenable to a variety of modifications and/or enhancements. For example, materials other than selenium or selenium alloys can be deposited. Also, the number of auxiliary chambers can vary based on the resulting semiconductor article.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A deposition system, comprising:
a deposition chamber constructed so that a deposition process can be carried out within the deposition chamber;
a plurality of auxiliary chambers each disposed adjacent to the deposition chamber and separated by a corresponding door movable between a closed position wherein the auxiliary chamber can be maintained at a separate pressure from the deposition chamber, and an opened position wherein a container of material disposed within the auxiliary chamber can be moved into and out of the deposition chamber;
a support constructed and arranged within the deposition chamber for supporting a work piece so that the work piece is positioned above each container as the container is moved into and out of the deposition chamber; and
a control subsystem for sequentially moving a container of material from each of the auxiliary chambers into and out of the deposition chamber so as to deposit material from each of the containers onto the work piece in a sequential manner.

2. A deposition system according to claim 1, wherein the control subsystem is configured and arranged to proceed through a sequence of steps for each of the auxiliary chambers including: equalizing the pressure in an auxiliary chamber and the deposition chamber, opening the door therebetween, moving the container from the auxiliary chamber into the deposition chamber so as to deposit material from the container onto the work piece, moving the container back to the corresponding auxiliary chamber and closing the door, and subsequently repeating the sequence of steps for each of the auxiliary chambers.

3. A deposition system according to claim 1, wherein the auxiliary chamber is arranged so as to prepare the material in the container so that when moved into the deposition chamber the material can be vaporized below and deposited on the work piece.

4. A deposition system according to claim 1, further including a pumping subsystem for separately creating a vacuum in each of the auxiliary chambers and the deposition chamber.

5. A deposition system according to claim 1, wherein the support is rotatably supported in the deposition chamber so that the work piece can be supported upside down, and rotated while a container is below it in the deposition chamber.

6. A deposition system according to claim 1, further including a plurality of the containers and a removable cover for each of the containers so that when the container is positioned in an auxiliary chamber it can be covered and the material in the container prepared for a deposition process in the deposition chamber, and when the container is positioned in the deposition chamber, the cover can be removed and the material can be vaporized below and deposited on the work piece.

7. A deposition system according to claim 6, further including a heating subsystem for heating each auxiliary chamber so that the material in a container disposed within the auxiliary chamber can be heated to a molten state prior to the container being moved into the deposition chamber.

8. A deposition system according to claim 1, wherein at least some of the containers include at least one material different from the material in the other containers

9. A deposition system according to claim 8, wherein one of the materials comprises p-type selenium and another material comprises n-type selenium.

10. A method of making a semiconductor component in a system comprising a deposition chamber constructed so that a deposition process can be carried out within the deposition chamber; and a plurality of auxiliary chambers each disposed adjacent to the deposition chamber and separated by a corresponding door movable between a closed position wherein the auxiliary chamber can be maintained at a separate pressure from the deposition chamber, and an opened position wherein a container of material disposed within the auxiliary chamber can be moved into and out of the deposition chamber; the method comprising;
supporting a work piece so that the work piece is positioned above each container as the container is moved into and out of the deposition chamber; and
sequentially moving a container of material from each of the plurality of auxiliary chambers into and out of the deposition chamber so as to deposit material from each of the containers onto the work piece in a sequential manner.

11. A method according to claim 10, wherein sequentially moving a container of material from each of the plurality of auxiliary chambers into and out of the deposition chamber includes equalizing the pressure in an auxiliary chamber and the deposition chamber, opening the door therebetween, moving the container from the auxiliary chamber into the deposition chamber so as to deposit material from the container onto the work piece, moving the container back to the corresponding auxiliary chamber and closing the door, and subsequently repeating the sequence of steps for each of the auxiliary chambers.

12. A method according to claim 10, further including preparing the material in each container so that when moved into the deposition chamber the material can be vaporized below and deposited on the work piece.

13. A method according to claim 10, further including separately creating a vacuum in each of the auxiliary chambers and the deposition chamber.

14. A method according to claim 10, further including rotatably supporting the work piece in the deposition chamber so that the work piece can be supported upside down, and rotated while a container is below it in the deposition chamber.

15. A method according to claim 10, further including covering each container when the container is positioned in an auxiliary chamber so that the material in the container can be prepared for a deposition process in the deposition chamber, and uncovering the container when the container is positioned in the deposition chamber so that the material in the container can be vaporized below and deposited on the work piece.

16. A method according to claim 15, further including heating each auxiliary chamber so that the material in a container disposed within the auxiliary chamber can be heated to a molten state prior to the container being moved into the deposition chamber.

17. A method according to claim 10, wherein at least some of the containers include at least one material different from the material in the other containers

18. A method according to claim 17, wherein one of the materials comprises p-type selenium and another material comprises n-type selenium.
